(19) United States
(12) Patent Application Publication
(10) Pub. No.: US 2010/0001432 A1
(43) Pub. Date: Jan. 7, 2010

(54) APPARATUS FOR PASSIVATING A COMPONENT AND METHOD FOR PRODUCING THE APPARATUS

(76) Inventors: Stefan Mueller, Wasserburg (DE); Frieder Haag, Wannweil (DE)

Correspondence Address: KENYON & KENYON LLP, ONE BROADWAY, NEW YORK, NY, 10004, US

(21) Appl. No.: 12/305,056

(22) PCT Filed: Sep. 19, 2007
(86) PCT No.: PCT/EP2007/059894

§ 371 Date: May 4, 2009

(30) Foreign Application Priority Data
Nov. 9, 2006 (DE) 10 2006 052 811.5
Aug. 16, 2007 (DE) 10 2007 038 515.5

(51) Int. Cl. H01L 21/56; G01L 9/00

(52) U.S. Cl. 264/272.17; 425/542

(57) ABSTRACT

An apparatus for passivating a component in a housing, the component including a substrate; the housing completely surrounding the substrate in a first substrate region; the housing being provided opened in a second substrate region, using an opening; the diepad completely surrounding the substrate in a plane parallel to the principal plane of extension of the substrate.

### FIELD OF THE INVENTION

The present invention relates to an apparatus for passivating a component.

### BACKGROUND INFORMATION

A method is described in German Patent Application No. DE 199 29 026 A1 in which a semiconductor pressure transducer is mounted on an assembly section of a leadframe, the semiconductor pressure transducer is electrically connected to contact sections of the leadframe, the leadframe is inserted in an injection-molding die together with the semiconductor pressure transducer, and subsequently the semiconductor pressure transducer is surrounded in the injection-molding die with a housing made of mold compound, during the injection molding a stamp in the injection molding die being situated through a gap at a distance from the side of the mounting section facing away from the semiconductor pressure transducer, and being controlled with respect to its temperature. However, the relatively complicated construction of the stamp is a disadvantage in this case. Thus, the stamp has to be connected to a heating device or a cooling device. In addition, even slight tolerance deviations in the size and the shape of the stamp lead to damage of the chip, either by pressure of the stamp on the chip or by the penetration of the mold compound into too large a gap between the stamp and the semiconductor pressure transducer.

### SUMMARY

An example device and method according to the present invention for passivating a component has the advantage that tolerances in the injection molding die are able to be compensated for and, in addition, a subsection of the substrate is able to be protected from the mold compound. A component, within the meaning of the present invention, may also be taken to mean a combination of individual components and components that are packaged with one another. For instance, a plurality of chips and a wire bonding connection between the chips and the individual components is able to represent a component. Particularly in the mass production of housings for components, changes in the injection molding die may be created by the acting forces. If the housing is produced from two injection molding die halves which together form a cavity, shifts of the injection molding die halves with respect to each other may occur, which leads to sealing problems at their contact surfaces or a large material stress. These problems are reduced by the present invention. For this purpose, the apparatus according to the present invention has a mounting support which will also be designated as a diepad below. At least subsections of the diepad are located in a plane generally parallel to the main extension plane of the substrate, the diepad generally completely surrounding the substrate in this plane. According to the present invention, it is thereby advantageously possible that the injection molded halves do not directly close against each other, but close generally completely on the diepad. In an injection molding method, the molding compound is introduced into the cavity of the injection molding die at a high pressure and that the molding compound may be of very low viscosity, depending on the material used.

Therefore, the contact surfaces of the injection molding die halves, by which the injection molding die halves are in contact with each other during production of the apparatus according to the present invention, have to close against each other as much as possible without unobstructed gaps. In regions in which the contact surfaces of the injection molding die halves do not close tightly with each other, molding compound may flow out and reach areas of the housing to be produced, which should really remain free of molding compound. In this case, a so-called overinjection has taken place. In particular, an overinjection of sensors that should actually be left free leads to the production of scrap, which is costly. By a slight deformability of the diepad, it is, however, possible, according to the present invention, to compensate for slight tolerances of the contact surfaces of the injection molding die, and also to the wear of the injection molding die, since the hard materials of the injection molding die halves are no longer pressed directly against each other using great pressure, but a buffer in the form of the diepad is located between the injection molding die halves.

It is also especially preferred if at least subsections of the diepad are provided crimped. By crimping, within the meaning of the present invention, one should understand an object being changed using a double bending with respect to its local main extension plane. The region between the two bends of the double bending preferably has an angle of 45° to the parts of the diepad that were not crimped. However, other angles are also a possibility.

Furthermore, it is preferred if the passivating of the component is provided using injection molding of the component, using a molding compound, the substrate being generally completely surrounded only in a first substrate region by the housing. It is then possible, according to the present invention, to protect the chip formed by the substrate from environmental influences, such as moisture or dirt. On the other side, the second substrate region, that is not surrounded by the housing, is able to be protected from the influencing by the housing. Thus, a thermal expansion of the housing is not directly able, for example, to act directly on the second substrate region. In the second substrate region, for example, there may be located an active sensor region which is thus better protected from stresses induced by the housing. Consequently, it is preferred, according to the present invention, if the component having a housing is a sensor system. The substrate may be, for instance, a semiconductor substrate, preferably a silicon substrate, especially an SOI substrate. The injection molding of the component may take place, for instance, using a mold compound in an appropriate transfer molding method. However, other methods for producing the housing are also possible, as are other substrates than the one mentioned above.

The crimped region of the diepad is especially preferably located in the center plane of the substrate. By center plane of the substrate one should understand, in this instance, a plane that is located generally parallel to the plane of the principal extension, and which is at a height corresponding generally to the middle of the substrate. Because of this, it is possible, according to the present invention, to equalize the height of the substrate, so that the tool is able to be implemented generally in the same manner on both sides. The diepad, in this context, has a recess in an especially preferred way, the second substrate region being provided in the region of the recess.

### BRIEF DESCRIPTION OF THE DRAWINGS

Exemplary embodiments of the present invention are depicted in the figures and described in greater detail below.

FIG. 1 schematically shows a sectional representation of an example apparatus according to the present invention.

FIG. 2 schematically represents the apparatus in a top view.

FIG. 3 schematically shows a section through the cavity of an injection molding die.

### DETAILED DESCRIPTION OF EXAMPLE EMBODIMENTS

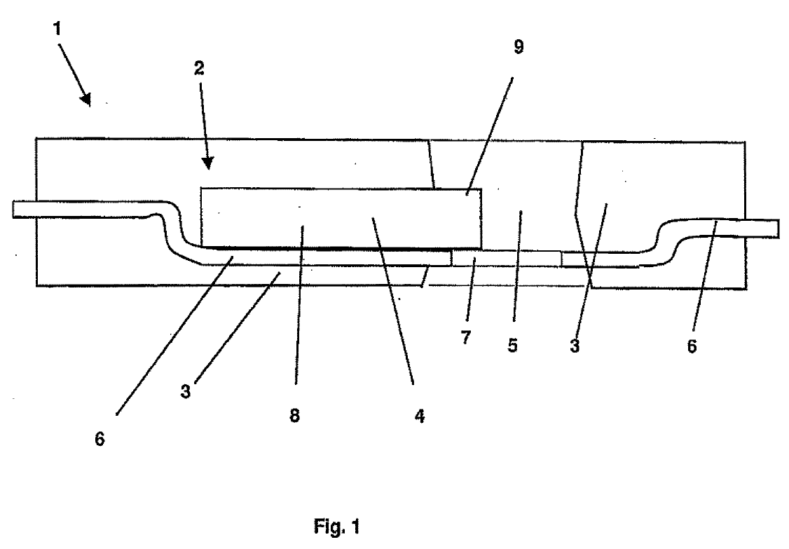

FIG. 1 schematically shows a sectional representation through an apparatus 1 having a housing 3. Housing 3 partially encloses a substrate 4, in this instance. Substrate 4 may be divided into two regions—a first substrate region 8 and a second substrate region 9. First substrate region 8 is protected from damage and dirt by housing 3. Second substrate region 9 is shown in an opening 5 of housing 3 and may, for example, have an active sensor region. A mounting support 6, which will also be designated as diepad 6 below, is located under first substrate region 8, diepad 6 having a recess 7. This recess 7 is located in the region of opening 5. A subsection of diepad 6 is drawn by crimping into the center plane of substrate 4, parallel to its principal direction of extension. It is thereby possible to compensate for the thickness of substrate 4, according to the present invention. In the exemplary embodiment, component 2 includes substrate 4 and diepad 6. Apparatus 1 includes component 2 along with housing 3 in the exemplary embodiment.

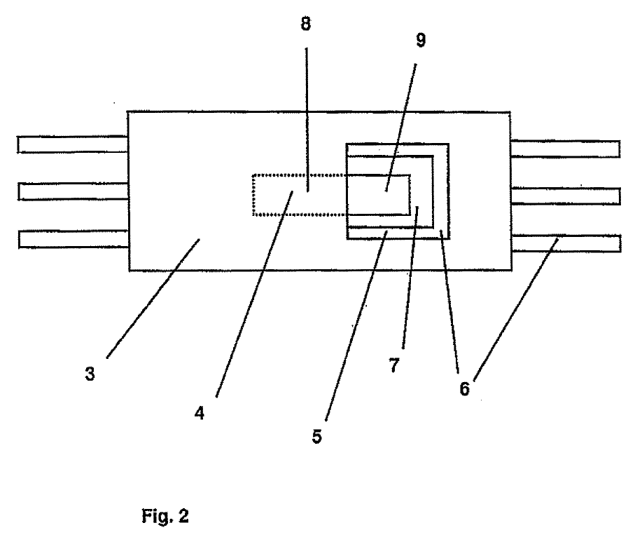

FIG. 2 shows a schematic top view onto apparatus 1, according to the present invention. Second substrate region 9 of substrate 4 is provided in opening 5 of housing 3. First substrate region 8 is enclosed by housing 3, and is therefore drawn in in dotted lines. Diepad 6 is also shown in opening 5. Second substrate region 9 is located in opening 5 and in recess 7 of diepad 6, and is therefore not able to be influenced by housing 3 or diepad 6.

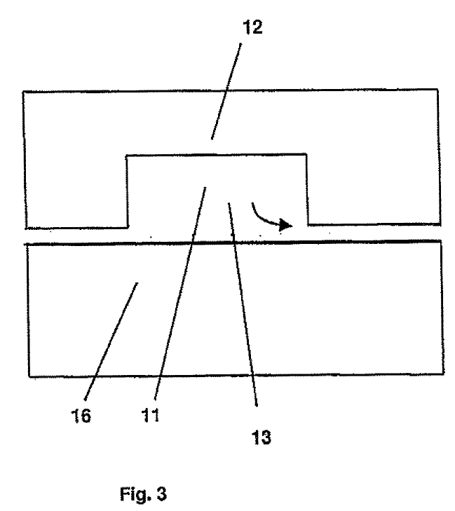

FIG. 3 shows schematically a section through a cavity 11 of an injection molding die. A first injection molding die half 12 is supposed to lie on component 2 (not shown in FIG. 3) or on a second injection molding die 16. On account of wear of injection molding die halves 12, 16 or by the inexact closing of injection molding die halves 12, 16 a gap may be created through which mold compound 13 may squeeze through in the direction of the arrow, for example. An overinjection may occur, because of this, of regions that should actually remain exposed, which under certain circumstances interferes with component 2 that is located in housing 3. In the production of housing 3 (with component 2), diepad 6 is located between two injection molding die halves 12, 16. Thus, slight tolerances during closing of the injection molding die may be compensated for by a deformation in diepad 6. It is thereby prevented that mold compound 13 is squeezed into regions that should actually remain free of it.

1-8. (canceled)

9. An apparatus for passivating a component in a housing, the component including a substrate, the housing completely surrounding the substrate in a first substrate region, the housing being open in a second substrate region, wherein a mounting support completely surrounds the substrate in a plane parallel to a principal plane of extension of the substrate.

10. The apparatus as recited in claim 9, wherein the mounting support is crimped.

11. The apparatus as recited in claim 10, wherein a section of the mounting support is provided in a center plane of the substrate due to the crimping.

12. The apparatus as recited in claim 9, wherein the mounting support has a recess.

13. The apparatus as recited in claim 12, wherein the second substrate region is provided in a region of the recess of the mounting support.

14. The apparatus as recited in claim 9, wherein the passivation of the component is provided by injection molding of the component using a mold compound, the substrate being completely surrounded by the housing only in the first substrate region.

15. The apparatus as recited in claim 9, wherein the component, the substrate, and the housing comprise a sensor system.

16. A method for producing an apparatus for passivating a component in a housing, the housing completely surrounding the substrate in a first substrate region, the housing being open in a second substrate region, the method comprising:
providing a mounting support to completely surround the substrate in a plane parallel to a principal plane of extension of the substrate, a space region of the housing being completely sealed between the mounting support and a tool.
